(19) United States
(12) Patent Application Publication
(10) Pub. No.: US 2026/0047411 A1
(43) Pub. Date: Feb. 12, 2026

(54) DAMASCENE INTERCONNECTS WITH BILAYER LINER

(71) Applicant: INTERNATIONAL BUSINESS MACHINES CORPORATION, Armonk, NY (US)

(72) Inventors: Takeshi Nogami, Schenectady, NY (US); Andrew Herbert Simon, FISHKILL, NY (US); Ching-Tzu Chen, Ossining, NY (US); Kevin Wayne Brew, Niskayuna, NY (US); Martin Michael Frank, Dobbs Ferry, NY (US); Debarghya Sarkar, Latham, NY (US); Atharv Jog, Albany, NY (US); Juntao Li, Cohoes, NY (US); SON NGUYEN, Schenectady, NY (US); Wei-Tsu Tseng, Hopewell Junction, NY (US); Daniel Charles Edelstein, White Plains, NY (US)

(21) Appl. No.: 18/796,399

(22) Filed: Aug. 7, 2024

(51) Int. Cl. H01L 21/768; H01L 23/528; H01L 23/532

(52) U.S. Cl. CPC H01L 21/76849; H01L 21/76805; H01L 21/76846; H01L 21/76858; H01L 21/76879; H01L 23/5283; H01L 23/53238

(57) ABSTRACT

A device includes a dielectric layer and a conductor in the dielectric layer including a first conductive material. A conductive liner wraps around the conductor and includes a second conductive material. A barrier layer is at an interface between the conductive liner and the dielectric layer, including a first oxide and a second oxide.

### BACKGROUND

The present invention generally relates to semiconductor device fabrication and, more particularly, to the formation of conductive contacts in such a device.

As feature sizes for the fabrication of semiconductor devices continue to scale down, the use of copper becomes increasingly challenging. A barrier wetting layer is used, for example to prevent diffusion of the copper into the surrounding dielectric material, but this layer takes up a larger fraction of the cross-sectional area of the contact as the size of the contact is reduced. As a result, the fraction of the contact that is copper decreases, and the resistance of the contact increases. Other conductive materials, such as cobalt, may be used to fabricate contacts and interconnects, but these materials face their own challenges, and may have relatively poor diffusion barrier performance and poor adhesion to insulators. Furthermore, non-uniformity in the resulting line resistance increases as the size scales down, due to non-uniformity in the metal height resulting from polishing.

### SUMMARY

A device includes a dielectric layer and a conductor in the dielectric layer including a first conductive material. A conductive liner wraps around the conductor and includes a second conductive material. A barrier layer is at an interface between the conductive liner and the dielectric layer, including a first oxide and a second oxide.

A device includes a dielectric layer and a conductor in the dielectric layer including a first conductive material. A conductive liner wraps around the conductor and includes a second conductive material. A barrier layer is at an interface between the conductive liner and the dielectric layer, including a manganese oxide and a metal oxide. The manganese oxide fills gaps between grain boundaries of the metal oxide.

A device includes a dielectric layer and a copper conductor in the dielectric layer including a first conductive material. A conductive liner includes cobalt or ruthenium and wraps around the conductor. A barrier layer is at an interface between the conductive liner and the dielectric layer, including a manganese oxide and a metal oxide. The manganese oxide fills gaps between grain boundaries of the metal oxide. A conductive structure is in direct contact with the conductive liner.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view of a step in the fabrication of a conductive interconnect in a dielectric layer, having a bilayer liner layer, that shows the formation of a trench in the dielectric layer, in accordance with an embodiment of the present invention;

FIG. 2 is a cross-sectional view of a step in the fabrication of a conductive interconnect in a dielectric layer, having a bilayer liner layer, that shows the formation of a first alloy layer that includes a conductor metal and an oxygen-reactive metal, in accordance with an embodiment of the present invention;

FIG. 3 is a cross-sectional view of a step in the fabrication of a conductive interconnect in a dielectric layer, having a bilayer liner layer, that shows the formation of a second alloy layer that includes a conductor metal and manganese, in accordance with an embodiment of the present invention;

FIG. 4 is a cross-sectional view of a step in the fabrication of a conductive interconnect in a dielectric layer, having a bilayer liner layer, that shows the formation of an interface oxide layer at the surface of the dielectric layer by diffusion of materials from the first alloy layer and the second alloy layer, in accordance with an embodiment of the present invention;

FIG. 5 is a cross-sectional view of a step in the fabrication of a conductive interconnect in a dielectric layer, having a bilayer liner layer, that shows removal of material from the first alloy layer and the second alloy layer, in accordance with an embodiment of the present invention;

FIG. 6 is a cross-sectional view of a step in the fabrication of a conductive interconnect in a dielectric layer, having a bilayer liner layer, that shows formation of conductive liner material on a top surface of a remaining conductor structure, in accordance with an embodiment of the present invention;

FIG. 7 is a block/flow diagram of a method of forming a conductive interconnect in a dielectric layer, having a bilayer liner, in accordance with an embodiment of the present invention; and

FIG. 8 is a cross-sectional view of an interface between layers that shows discrete regions of manganese oxide and another metal oxide, in accordance with an embodiment of the present invention.

### DETAILED DESCRIPTION

A metal oxide layer, with manganese assistance, may be used as a diffusion barrier for a copper conductor with cobalt wrap-around. The metal oxide layer provides a superior stop to a chemical mechanical planarization (CMP), which improves contact height uniformity. Additionally, the manganese fills in gaps between regions of metal oxide in the metal oxide layer, thereby improving its performance as a diffusion barrier for the conductor.

Referring now to FIG. 1, a cross-sectional view of a step in the fabrication of an interconnect is shown. A conductive structure 104 is formed in a dielectric layer 102. The dielectric layer 102 may include an interlayer dielectric, a back-end-of-line layer, or any other appropriate dielectric layer and may be formed from, e.g., silicon dioxide or any other appropriate dielectric material, such as a low-k dielectric material such as SiCNOH, SiCNH, or nanolaminated metal silicate. A low-k dielectric is a material that has a dielectric constant k which is below that of silicon dioxide. Such materials may be used to reduce parasitic capacitances between conductive lines such as interconnects.

The conductive structure 104 may make an electrical connection with an underlying structure, such as an active or passive circuit component. For example, the conductive structure 104 may be a lower-layer metal interconnect. Alternatively, the conductive structure 104 may be a contact to a transistor or other passive or active circuit component. The conductive structure 104 may be formed from any appropriate conductive metal such as, e.g., tungsten, nickel, titanium, molybdenum, tantalum, copper, platinum, silver, gold, ruthenium, iridium, rhenium, rhodium, cobalt, aluminum, manganese and alloys thereof. The conductive structure 104 may alternatively be formed from metal nitrides such as titanium nitride, metal silicides such as platinum silicide, titanium silicide, cobalt silicide, and nickel silicide, or a doped semiconductor material such as, e.g., doped polysilicon.

A trench 106 and via 108 may be formed in the dielectric layer 102. It is contemplated that the trench 106 may be used to form an interconnect that provides a conductive path in the plane of the dielectric layer 102, and that the via 108 may be used to form an interconnect that provides a conductive path through the dielectric layer 102, but any appropriate opening shape in the dielectric layer 102 may be formed as an alternative.

The trench 106 and the via 108 may be formed by photolithographic patterning. For example, a pattern may be produced by applying a photoresist to the surface to be etched. The photoresist may be exposed to a pattern of radiation, which causes a chemical chance to the photoresist material. The pattern may then be developed into the photoresist using a resist developer. Once the patterning of the photoresist is completed, the sections covered by the photoresist are protected while the exposed regions are removed using a selective etching process that removes the unprotected regions.

Reactive ion etching (RIE) is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. As used herein, the term “selective” in reference to a material removal process denotes that the rate of material removal for a first material is greater than the rate of removal for at least another material of the structure to which the material removal process is being applied. After patterning, a timed RIE may be used to form the trench 106 and the via 108 in the dielectric layer. In some cases, multiple different patterning steps may be used to create these openings, for example using a first pattern to define the trench 106 and a second pattern to define the deeper via 108.

The present embodiments are described with respect to the fabrication of an interconnect that is in electrical contact with the underlying conductive structure 104. However, it should be understood that the present embodiments are not limited to such an arrangement, and that some embodiments may include interconnects that are instead in electrical contact with overlying conductive structure or that make an electrical connection between conductive structures on a same plane as the interconnect. As used herein, the term “electrical contact” and “electrical connection” refer to a relationship between structures whereby electrical current can freely pass from one structure to the other.

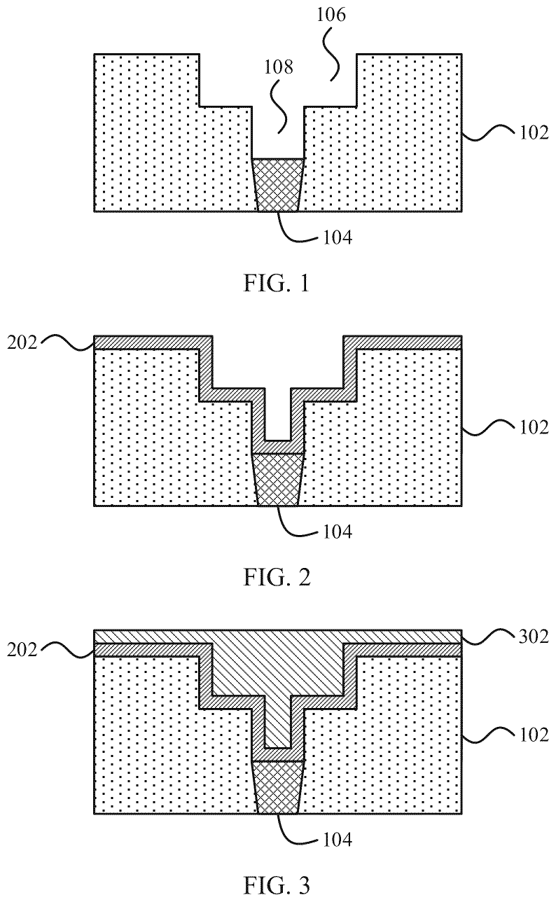

Referring now to FIG. 2, a cross-sectional view of a step in the fabrication of an interconnect is shown. A first alloy layer 202 is conformally deposited on the surfaces of the trench 106 and the via 108. The first alloy layer 202 may be, for example, an alloy of cobalt or ruthenium and another metal, such as a metal that will react with oxygen to form various metal oxide. Exemplary metals that may be used in the first alloy layer 202 include zinc, chromium, aluminum, nickel, zirconium, hafnium, and titanium. In some embodiments, the first alloy layer 202 may include cobalt or ruthenium and multiple such other metals, such as an alloy of cobalt, aluminum, and zinc. The metals of the first alloy layer 202 may be selected to provide particular specific orientation and/or directional electrical resistivity or dielectric constant values. For example, resistivities for conducting oxides between 100 μΩ-cm and 1000 μΩ-cm are contemplated, as are dielectric constants for insulating metal oxides between 4 and 20.

Various deposition processes may be used herein for different purposes, such as chemical vapor deposition (CVD), physical vapor deposition (PVD), atomic layer deposition (ALD), or gas cluster ion beam (GCIB) deposition. Some deposition processes, such as ALD, may deposit material conformally, whereas others, such as PVD or GCIB, may provide a more directional deposition. CVD may range from highly conformal to highly non-conformal depending on the formulation. Thus the deposition of the first alloy layer 202 may be performed with ALD or CVD, as appropriate.

In some cases, the first alloy layer 202 may be formed by successive depositions, for example alternating between cobalt or ruthenium and the additional metal or metals. The first alloy layer 202 may be deposited to an exemplary thickness of less than 1.5 nm. In some cases, the first alloy layer 202 may be formed by a uniform deposition of cobalt or ruthenium along with the additional metal or metals.

Referring now to FIG. 3, a cross-sectional view of a step in the fabrication of an interconnect is shown. A second alloy layer 302 is deposited to fill the trench 106 and the via 108 using any appropriate deposition process, such as PVD. After deposition, a reflow process may be performed to melt the material of the second alloy layer 302 and ensure that it fully fills the trench 106. The second alloy layer 302 may be formed from a second alloy material that includes copper and manganese. For example, the second alloy layer 302 may include copper that is doped with manganese at an atomic percentage between 0.1% and 10%, with a particularly contemplated range being copper doped with manganese at an atomic percentage between 0.5% and 2.0%.

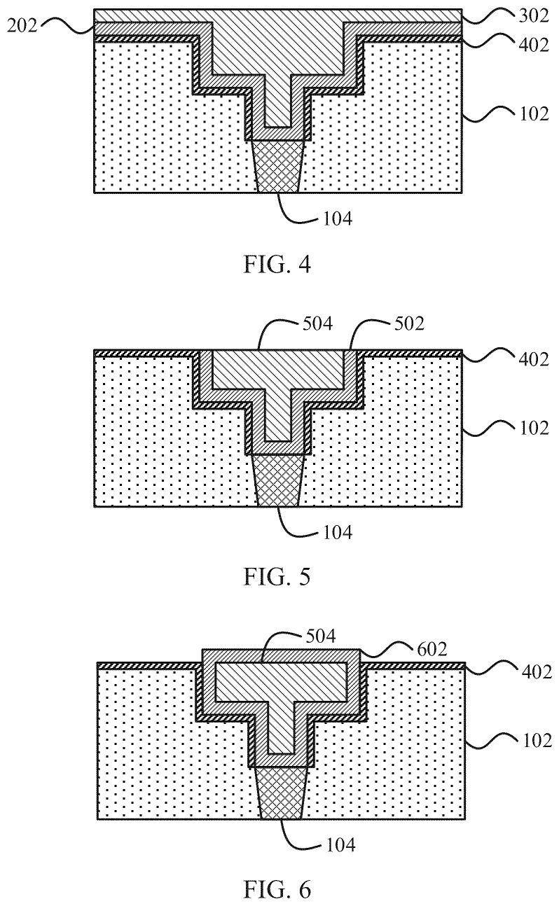

Referring now to FIG. 4, a cross-sectional view of a step in the fabrication of an interconnect is shown. After deposition and the reflow process of the second alloy layer 302, metal from the first alloy layer 202 and the manganese of the second alloy material may diffuse to the interface with the dielectric layer 102 and may react with oxygen there to form interface layer 402, which includes oxides of the diffused materials. The metal from the first layer, such as zinc, will react with oxygen at the interface to form a metal oxide, and the manganese will form a manganese oxide.

The reflow process described above may help to drive the metal of the first alloy layer 202 to the interface with the dielectric layer 102, where it reacts with the material of the dielectric layer 102 and oxidizes. As a result of this diffusion, the relative proportion of cobalt or ruthenium in the first alloy layer 202 is increased. The portion of the first alloy layer 202 that is in contact with the conductive structure 104 will not oxidize and so will remain at roughly the original proportion between cobalt or ruthenium and the metal. The manganese in the second alloy layer 302 diffuses through the first alloy layer 202 toward the dielectric interface to seal grain boundaries in the metal oxide, thereby improving the barrier performance of the interface layer 402 relative to if it were composed of the metal oxide alone.

The low atomic radius and high mobility of the manganese results in that element out-diffusing into any pinholes or open grain boundaries in the metal oxide. The manganese reacts there with trace oxygen impurities to form MnO, MnSiO, or other such compounds, which plugs the openings, for example filling the open space between grain boundaries of neighboring metal oxide regions. Very little manganese remains in the copper after the reflow process, because the manganese preferentially diffuses and coalesces at the reactive interfaces with other materials at the copper surfaces.

Alternatively, a thin CuMn seed layer may be deposited on top of the first alloy layer 202, followed by the deposition of copper to fill the trench 106. After deposition, an annealing process is performed to drive the metal of the first alloy layer 202 and the manganese in the CuMn seed layer to the interface with the dielectric layer 102, forming a manganese-oxide metal-oxide interface layer 402.

Referring now to FIG. 5, a cross-sectional view of a step in the fabrication of an interconnect is shown. A CMP process is performed that removes excess material from the second alloy layer 302 and the first alloy layer 202. CMP is performed using, e.g., a chemical or granular slurry and mechanical force to gradually remove upper layers of the device. The slurry may be formulated to be unable to dissolve, for example, the metal oxide of the interface layer 402, resulting in the CMP process's inability to proceed any farther than that layer.

For example, if the interface layer 402 includes aluminum oxide (Al₂O₃), a CMP may be formulated that stops very cleanly on that layer, resulting in a consistent height for the remaining second alloy material in conductor 504. In some cases, the same CMP may further remove material from the first alloy layer 202, producing liner 502. In other cases, a second CMP may be used to remove material from the first alloy layer 202.

While the CMP is shown as halting on the interface layer 402, it may alternatively be formulated to halt on the top surface of the dielectric layer 102, so that none of the oxide material remains on the top surface of the dielectric layer 102. In embodiments where the interface layer 402 is preserved on top of the dielectric layer 102, it may serve as an etch stop in patterning overlying layers.

Referring now to FIG. 6, a cross-sectional view of a step in the fabrication of an interconnect is shown. Additional cobalt or ruthenium is selectively deposited on the conductor 504, joining with the liner 502 to encapsulate the conductor 504, forming wrap-around liner 602. The selective deposition may be performed by CVD on a heated wafer with specific precursors, such as carbonyl cyclopentadiene and hydrogen. This leads to selective nucleation and growth of the metal on copper surfaces, not on insulators.

The resulting interconnect may have a relatively large fraction of copper. For example, in a trench 106 that has a width of about 10 nm, the conductor 504 within the trench 106 may have a width of greater than about 7 nm. This results in a lower line resistance than structures which have a thick barrier layer, such as when tantalum or tantalum nitride is used, as well as reducing capacitance, increasing breakdown voltages, and improving time-dependent dielectric breakdown, while maintaining good adhesion and diffusion-barrier properties.

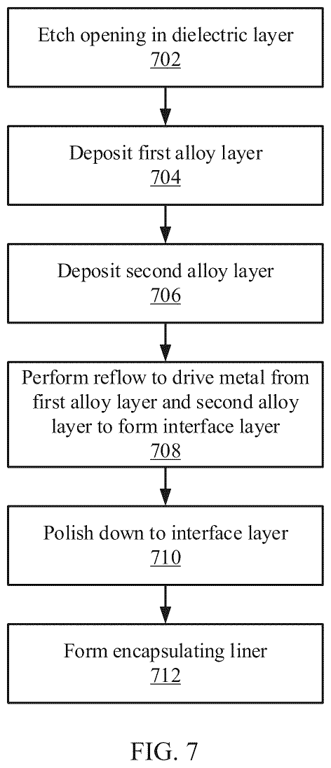

Referring now to FIG. 7, a method for fabricating an interconnect is shown. Block 702 etches an opening in a dielectric layer, for example including a trench 106 and/or a via 108. The opening may expose an underlying conductive structure 104. Block 704 then conformally deposits a first alloy layer 202 on surfaces of the opening. The deposition of the first alloy layer 202 may include a single deposition of multiple species or may include successive depositions of respective layers of different species. The deposition of the first alloy layer 202 may include a first metal, such as cobalt or ruthenium, and one or more additional metals that react with oxygen, such as zinc, chromium, aluminum, nickel, zirconium, hafnium, and titanium.

Block 706 deposits a second alloy layer 302 using any appropriate deposition process, filling the opening. The second alloy layer 302 may include a conductor metal, such as copper, and an additional metal, such as manganese. Block 708 performs a reflow by raising the temperature of the deposited materials. This causes the manganese within the second alloy layer 302 and the additional metal(s) of the first alloy layer 202 to diffuse to the interface between the first alloy layer 202 and the dielectric layer 102, reacting with oxygen in the dielectric layer and forming interface layer 402.

Block 710 removes excess material from the second alloy layer 302 and the first alloy layer 202 with one or more CMP polishes, stopping on the interface layer 402. The result is a uniform top surface of the remaining conductor 504, with a remaining portion of the first alloy layer 202 forming a liner 502 underneath the conductor 504. Block 712 then selectively deposits additional metal, such as cobalt or ruthenium, on top of the conductor 504, which combines with the liner 502 to form wrap-around liner 602 to encapsulate the conductor 504.

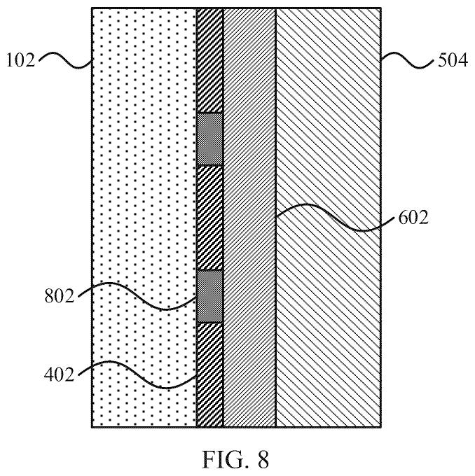

Referring now to FIG. 8, additional detail is shown on the interface between the dielectric layer 102 and the wrap-around liner 602. At this level of detail, the metal oxide of the interface layer 402 is shown as having gaps. These gaps may result from the formation of grain boundaries or other physical processes that result in incomplete coverage of the surface of the dielectric layer 102. The manganese that diffuses out from the second alloy layer 302 reacts with oxygen in these gaps of the metal oxide of the interface layer 402, resulting in the formation of manganese oxide regions 802 to fill the gaps and complete the barrier between the liner 602 and the dielectric layer 102.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of damascene contacts with metal oxide cobalt (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A device, comprising:
a dielectric layer;
a conductor in the dielectric layer including a first conductive material;
a conductive liner that wraps around the conductor and that includes a second conductive material; and
a barrier layer at an interface between the conductive liner and the dielectric layer, including a first oxide and a second oxide.

2. The device of claim 1, wherein the first oxide is manganese oxide and the second oxide is a metal oxide.

3. The device of claim 2, wherein the metal oxide includes a metal selected from the group consisting of zinc, chromium, aluminum, nickel, zirconium, hafnium, and titanium.

4. The device of claim 3, wherein the metal oxide includes at least two metals selected from the group consisting of zinc, chromium, aluminum, nickel, zirconium, hafnium, and titanium.

5. The device of claim 1, wherein the conductor includes copper and the conductive liner includes cobalt or ruthenium.

6. The device of claim 1, further comprising a conductive structure in electrical contact with the conductive liner.

7. The device of claim 6, wherein the conductive liner further includes a metal selected from the group consisting of zinc, chromium, aluminum, nickel, zirconium, hafnium, and titanium in a region in electrical contact with the conductive liner.

8. The device of claim 6, wherein the conductive liner further includes at least two metals selected from the group consisting of zinc, chromium, aluminum, nickel, zirconium, hafnium, and titanium in a region in electrical contact with the conductive liner.

9. The device of claim 6, wherein the conductive liner is in direct contact with the conductive structure, without the barrier layer between them.

10. The device of claim 1, wherein the first oxide fills gaps between grain boundaries of the second oxide.

11. The device of claim 1, wherein the barrier layer extends laterally on a top surface of the dielectric layer.

12. A device, comprising:
a dielectric layer;
a conductor in the dielectric layer including a first conductive material;
a conductive liner that wraps around the conductor and that includes a second conductive material; and
a barrier layer at an interface between the conductive liner and the dielectric layer, including a manganese oxide and a metal oxide where the manganese oxide fills gaps between grain boundaries of the metal oxide.

13. The device of claim 12, wherein the metal oxide includes a metal selected from the group consisting of zinc, chromium, aluminum, nickel, zirconium, hafnium, and titanium.

14. The device of claim 13, wherein the metal oxide includes at least two metals selected from the group consisting of zinc, chromium, aluminum, nickel, zirconium, hafnium, and titanium.

15. The device of claim 12, wherein the conductor includes copper and the conductive liner includes cobalt or ruthenium.

16. The device of claim 12, further comprising a conductive structure in electrical contact with the conductive liner.

17. The device of claim 16, wherein the conductive liner includes a metal selected from the group consisting of zinc, chromium, aluminum, nickel, zirconium, hafnium, and titanium in a region in electrical contact with the conductive liner.

18. The device of claim 16, wherein the conductive liner includes at least two metals selected from the group consisting of zinc, chromium, aluminum, nickel, zirconium, hafnium, and titanium in a region in electrical contact with the conductive liner.

19. The device of claim 12, wherein the barrier layer extends laterally on a top surface of the dielectric layer.

20. A device, comprising:
a dielectric layer;
a copper conductor in the dielectric layer including a first conductive material;
a conductive liner that includes cobalt or ruthenium and that wraps around the conductor;
a barrier layer at an interface between the conductive liner and the dielectric layer, including a manganese oxide and a metal oxide where the manganese oxide fills gaps between grain boundaries of the metal oxide; and
a conductive structure in direct contact with the conductive liner.
